(19) United States
(12) Patent Application Publication
(10) Pub. No.: US 2007/0264815 A1
(43) Pub. Date: Nov. 15, 2007

(54) Method for fabricating semiconductor device

(76) Inventors: Yoshinori Takamori, Kyoto (JP); Naoyuki Baba, Niigata (JP); Norishige Aoki, Okayama (JP)

Correspondence Address: MCDERMOTT WILL & EMERY LLP, 600 13TH STREET, NW, WASHINGTON, DC, 20005-3096, US

(21) Appl. No.: 11/797,249

(22) Filed: May 2, 2007

(30) Foreign Application Priority Data
May 9, 2006 (JP) 2006-129861

(51) Int. Cl. H01L 21/44

(52) U.S. Cl. 438/617

(57) ABSTRACT

The method of fabricating a semiconductor device according to the present invention is applied to a semiconductor device fabricated by forming a seed film in recesses formed in an interlayer film and forming a thick film embedded in the recesses by electrolytic plating using the seed film as an electrode. In this fabrication method, the maximum length of time until the electrolytic plating is started after the completion of the seed film is limited based on the formation of the seed film in the recesses. The maximum time is reduced as the recesses have higher aspect ratios, preventing a void from being formed in the recesses during the plating, thereby obtaining highly reliable wiring.

### CROSS-REFERENCE TO RELATED APPLICATION

The present application claims the benefit of patent application number 2006-129861, filed in Japan on May 9, 2006, the subject matter of which is incorporated herein by reference.

### BACKGROUND OF THE INVENTION

1. Field of the Invention

The present invention relates to a method for fabricating a semiconductor device and particularly relates to fabrication of wirings used in a semiconductor device.

2. Description of the Related Art

Multilayer wiring structures are extensively used and wire intervals in a wiring layer become smaller as semiconductor devices become smaller (more highly integrated). In such semiconductor devices, signal delay is a factor in restricting the operation speed of the semiconductor devices. Signal delay predominantly results from delay of signals transferred through wiring, namely wiring delay. The wiring delay is presented by the product of inter-wiring capacity and wiring resistance (time constant). The smaller the time constant is, the smaller the wiring delay.

For smaller inter-wiring capacity, for example, it is useful to reduce the dielectric constant of insulating layers formed between the wirings. Therefore, recent semiconductor devices utilize low dielectric constant films containing impurities such as carbon and fluorine or porous films (porous films having a dielectric constant of approximately 2.5) instead of silicon oxide films.

On the other hand, for a smaller wiring resistance, copper wiring materials are utilized because they have lower resistance than conventionally used aluminum. However, copper is easily oxidized. Oxygen in the atmosphere gradually enters and diffuses from the surface to the inside and forms copper oxides. The copper oxides have high resistance and contribute to increased wiring resistance. Moreover, because of the difficulty in etching copper, the damascene process is used to form multilayer wiring. In the damascene process, a trench pattern is formed in an insulating film by etching and copper is embedded in the trench pattern. Then, excessive copper on the insulating film is removed by CMP (chemical mechanical polishing), embedding the wiring in the trench pattern.

Generally a copper film is formed on the insulating film by forming a thin copper film by PVD (physical vapor deposition) and then forming a thick copper film by electrolytic plating. In other words, a semiconductor substrate on which a thin copper film (a seed film) is formed by PVD is immersed in the plating bath of a plating solution containing copper sulfate. A copper-plating film is formed on the seed film by applying voltage the seed film used as the cathode electrode.

In semiconductor devices having copper wiring, a high melting point conductive metal film is formed as a conductive barrier film on the insulating film before the seed film is formed so that copper does not diffuse into the insulating film. The conductive barrier film is made of, for example, titanium, tungsten, tantalum, or their nitrides. The conductive barrier film is formed as a monolayer or multilayer film (reference Japanese Laid-Open Publication No. 2000-91422 and H06-232098).

### SUMMARY OF THE INVENTION

In the above described prior art, the seed film on the conductive barrier film has locally varied thickness depending on the opening size and depth of the trench pattern.

A case that an upper copper wiring is formed on an interlayer insulating film 103 on a lower copper wiring 101 is described hereafter with reference to FIG. 12. First, a contact hole 110 is formed in the interlayer insulating film 103 at the connection between the upper wiring and the lower wiring using known lithographic and etching techniques. Then, a trench pattern 111 is formed on the surface of the interlayer insulating film 103 using known lithographic and etching techniques. After the trench pattern 111 is formed, a conductive barrier film 104 and a seed film 105 are sequentially formed using a PVD technique such as sputtering. The conductive barrier film 104 is made of tantalum, tungsten, or their nitrides. The seed film 105 is made of copper. In this case, the seed film 105 has significantly reduced thickness on the bottom and lower sidewall of the contact hole 110 (the area enclosed by the broken lines X in the figure). In this instance, a barrier film 102 such as a nitride film or a carbon-containing insulating film is formed on the lower copper wiring 101 before the interlayer insulating film 103 is formed in order to prevent copper from diffusing into the interlayer insulating film 103.

The semiconductor substrate on which the seed film 105 is formed as described above is transferred from the PVD unit to a plating unit where it is copper-plated. Meanwhile, the copper seed film 105 exposed on the surface of the semiconductor substrate is exposed to the atmosphere. The seed film 105 is gradually oxidized by oxygen in the atmosphere from the surface, transforming the copper into copper oxide. Particularly, the seed film 105 on the bottom and lower sidewall of the contact hole 110 where it has a reduced thickness is nearly completely transformed into copper oxide.

When the semiconductor substrate in the above state is immersed in a plating solution, the copper oxide formed on the surface of the seed film 105 is dissolved by plating solution containing copper sulfate. As soon as copper is exposed on the surface, the seed film 105 serves as the cathode electrode and is copper-plated. Therefore, the seed film 105 on the bottom of the contact hole, which is nearly completely transformed into copper oxide, is totally dissolved in the plating solution and the conductive barrier film 104 is exposed on the surface. The conductive barrier film 104 is conductive; however, its conductivity is significantly small compared with copper. Consequently, when voltage is applied to the seed film 105 for copper-plating, the area where the conductive barrier film 104 is exposed is not subject to a desired voltage because of voltage drop and copper-plating is inhibited.

On the other hand, the upper part of the contact hole 110 where the seed film 105 remains is copper-plated. In this way, the lower part of the contact hole 110 is not copper-plated while the upper part of the contact hole 110 is copper-plated, forming a void (space) is formed in the contact hole 110, causing defective filling.

Defective filling does not always lead to electrically disconnected wiring. Conductivity is preserved in some cases depending on the degree of disappearance of the seed film 105. Therefore, it is difficult to reliably detect the defective filling using electrical measurements. When conductivity is preserved in spite of defective filling, locally high wiring resistance occurs, with the problem that the wiring has low EM (electro migration) resistance and is significantly less reliable.

The above inconvenience is not particular to the dual damascene technique in which the contact hole 110 and trench pattern 111 are concurrently filled. In other words, the single damascene technique in which the contact hole 110 and trench pattern 111 are separately filled also has the same inconvenience. Recently, in an attempt to increase the film thickness on the bottom and sidewall of the contact hole, CVD (chemical vapor deposition) techniques have been used for forming the seed film instead of PVD techniques. However, there is the inconvenience that the copper seed film reacts with oxygen to form copper oxide no matter how it is formed.

The present invention is proposed in view of the above circumstances and has as its objective to provide a method of fabricating a semiconductor device in which defective filling due to disappearance of the seed film is prevented and highly reliable wiring is ensured.

In order to achieve the above objective, the present invention uses the flowing means. First, an interlayer insulating film is formed on a lower wiring in the method of fabricating a semiconductor device having a multiplayer wiring according to the present invention. Plural recesses are formed in the interlayer insulating film and a first conductive film is formed in the recesses formed in the interlayer insulating film. A second conductive film is formed on the first conducive film by electrolytic plating using the first conductive film as an electrode. In the method of fabricating a semiconductor device according to the present invention, the length of time until the electrolytic plating for forming the second conductive film is started after the completion of the first conductive film is limited to a specific length of time or less based on the formation of the first conductive film in the recesses.

With the above configuration, the thickness of the first conductive film that is oxidized before the start of forming the second conductive film after the completion of the first conductive film can be less than the thickness of the first conductive film, preventing the appearance of a void at the bottom of the recesses during the formation of the second conductive film and highly reliable wiring is formed. The specific length of time is determined according to the aspect ratio of the recesses. For example, the specific length of time can be 48 hours when the recesses have an aspect ratio of 2.4 or less.

In another method of fabricating a semiconductor device according to the present invention, first, an interlayer insulating film is formed on a lower wiring in the method of fabricating a semiconductor device having a multilayer wiring structure. Plural recesses are formed in the interlayer insulating film and a first conductive film is formed in the recesses formed in the interlayer insulating film. A second conductive film is formed on the first conductive film by electrolytic plating using the first conductive film as an electrode. Then, the semiconductor substrate on which the first conductive film is formed is maintained in an inert gas atmosphere until the electrolytic plating for forming the second conductive film is started after the completion of the first conductive film.

With the above configuration, the oxidization of the first conductive film before the electrolytic plating for forming the second conductive film is started after the completion of the first conductive film is prevented. Therefore, the appearance of a void at the bottom of the recesses during the formation of the second conductive film can be prevented and highly reliable wiring is formed.

With the present invention, the oxidization of the entire seed film into copper oxide is prevented when a thin copper film is formed as the seed film in the recesses in the interlayer insulating film. No area is found in the recesses where the seed film dissolves and disappears when the semiconductor substrate on which the seed film is formed is immersed in a plating solution for forming a copper-plating film by electrolytic plating using the seed film as an electrode. A copper-plating film can be formed in the recesses without any void. Consequently, a semiconductor device with highly reliable wiring can be fabricated.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view showing the fabrication process of a semiconductor device in an embodiment of the present invention.

FIG. 2 is a cross-sectional view showing the fabrication process of a semiconductor device in an embodiment of the present invention.

FIG. 3 is a cross-sectional view showing the fabrication process of a semiconductor device in an embodiment of the present invention.

FIG. 4 is a cross-sectional view showing the fabrication process of a semiconductor device in an embodiment of the present invention.

FIG. 5 is a cross-sectional view showing the fabrication on process of a semiconductor device in an embodiment of the present invention.

FIG. 6 is a cross-sectional view showing the fabrication on process of a semiconductor device in an embodiment of the present invention.

FIG. 7 is a cross-sectional view showing the fabrication process of a semiconductor device in an embodiment of the present invention.

FIG. 8 is a cross-sectional view showing the fabrication process of a semiconductor device in an embodiment of the present invention.

FIG. 9 is a cross-sectional view showing an evaluation pattern used in an embodiment of the present invention.

FIG. 10 is a cross-sectional view showing an evaluation pattern in which voids appear.

FIG. 11 is a graphical representation showing the dependency of void incidence rate on the aspect ratio and atmosphere exposure time.

FIG. 12 is a cross-sectional view of a semiconductor device for explaining the problems of the prior art method of fabricating a semiconductor device.

### DETAILED DESCRIPTION OF PREFERRED EMBODIMENTS

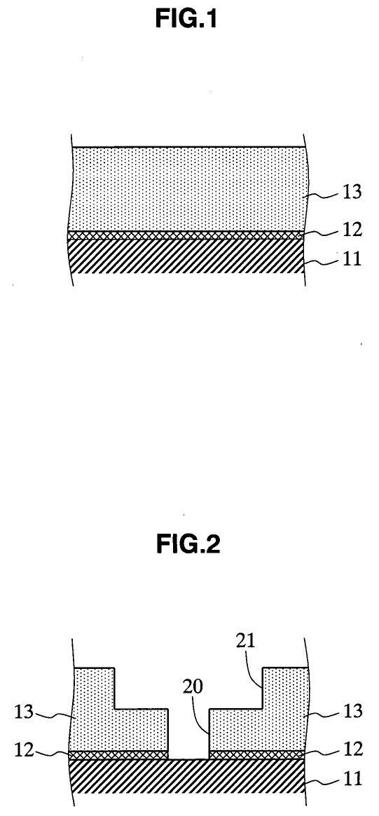

An embodiment of the method of fabricating a semiconductor device according to the present invention is described in detail hereafter with reference to the drawings. In the embodiment, the present invention is realized in a method of fabricating a semiconductor device by the dual damascene technique. FIGS. 1 to 8 are cross-sectional views showing the fabrication process of a semiconductor device having a multilayer wiring structure. In FIGS. 1 to 8, a semiconductor substrate on which semiconductor elements such as transistors and other wiring are formed is present below a lower wiring 11. However, the structure below the lower wiring 11 is not directly relevant to the present invention and, therefore, its explanation is omitted.

As shown in FIG. 1, first, an anti-diffusion barrier film 12 such as a carbon-added insulating film and a silicon nitride film is formed on the, for example copper, lower wiring 11 in the method of fabricating a semiconductor device of this embodiment. On the barrier film 12 is formed an interlayer insulating film 13 made of a low dielectric constant film containing impurities such as carbon and fluorine or a porous film (a porous film having a dielectric constant of approximately 2.5). In this embodiment, the interlayer insulating film 13 has a thickness of approximately 800 mm.

As shown in FIG. 2, a contact hole 20 and a trench pattern 21 in which wiring is embedded are formed in the interlayer insulating film 13 in sequence by known lithographic and etching techniques. At the bottom of the contact hole 20, the barrier film 12 is removed by etching and the lower wiring 11 is exposed. In this embodiment, the contact hole 20 has a diameter of approximately 200 nm and the trench pattern 21 has a width of approximately 420 nm and a depth of approximately 400 mm.

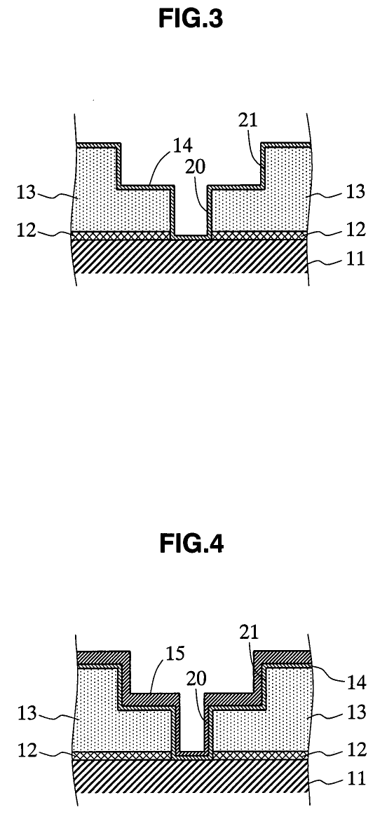

After the contact hole 20 and trench pattern 21 are formed, as shown in FIG. 3, a conductive barrier film 14 is formed by the PVD technique. After the above described etching, the semiconductor substrate is transferred to a PVD unit in the atmosphere. Therefore, a pre-treatment is conducted to remove the oxide film formed on the surface of the lower wiring 11 immediately before the conductive barrier film 14 is formed. The pre-treatment is a plasma etching using hydrogen or argon gas or their mixture gas or a reduction process by heating in hydrogen or argon gas or their mixture gas atmosphere.

After pre-treatment, the conductive barrier film 14 is formed, for example, by sputtering. The conductive barrier film 14 is a monolayer or multilayer film made of high meting point metal such as titanium, tungsten, and tantalum and their nitrides. The conductive barrier film 14 has a thickness of approximately 30 nm.

As shown in FIG. 4, a copper seed film 15 (a first conductive film) is formed on the conductive barrier film 14. The seed film 15 is formed generally by the PVD technique. For a finer pattern, the seed film 15 can be formed by the CVD or ALD (atomic layer deposition) technique so that the film on the bottom and sidewall of the contact hole 20 has increased thickness. For extremely fine wiring or contact, the conductive barrier film 14 can also be formed by the CVD or ALD technique. The thickness of the seed film 15 varies depending on the size of the contact hole 20 and trench pattern 21 and their aspect ratio (=opening depth/opening diameter). In this instance, the seed film 15 has a thickness of approximately 100 nm. After the conductive barrier film 14 and the seed film 15 are formed on the inner wall of the contact hole 20, the contact hole 20 has an inner diameter of approximately 170 nm.

It is preferable that the above pre-treatment and formation of the conductive barrier film 14 and the seed film 15 be conducted in a continuous manner in one and the same unit. However, the conductive barrier film 14 and the seed film 15 should be formed in separate, dedicated units in some cases. In such cases, for example, the pre-treatment and the formation of the conductive barrier film 14 are conducted in one and the same unit, the semiconductor substrate is transferred to a unit for forming the seed film 15, and then the seed film 15 is formed. In this instance, the conductive barrier film 14 is exposed to the atmosphere and oxide is formed on the surface. Therefore, it is preferable to conduct pre-treatment immediately before the seed film 15 is formed. After removal from the film-forming unit, the semiconductor substrate on which the seed film 15 is formed is stored in a specific storage box until the subsequent electrolytic plating is started.

In this embodiment, the electrolytic plating is started within 48 hours after the semiconductor substrate is stored in the storage box. In other words, the electrolytic plating is started on the semiconductor substrate within 48 hours after the seed film 15 is exposed to the atmosphere.

As described above, the seed film 15 is oxidized by oxygen in the atmosphere and transformed into copper oxide, which is an oxide of copper, after being exposed to the atmosphere. FIG. 5 shows the seed film 15 of which the surface is oxidized. As shown in FIG. 5, as a result of exposure to the atmosphere, the seed film 15 is evenly oxidized regardless of the pattern of the contact hole 20. Therefore, only a thin layer of copper remains under the copper oxide 16 on the bottom and lower sidewall of the contact hole 20 where the seed film 15 has a smaller thickness compared with the other parts. However, if the semiconductor substrate having the seed film 15 is electrolytic-plated within 48 hours after being exposed to the atmosphere, the seed film 15 is not oxidized through the entire thickness. Consequently, no area is found in the recesses where the entire seed film 15 dissolves and disappears when the semiconductor substrate is immersed in a copper sulfate-containing plating solution.

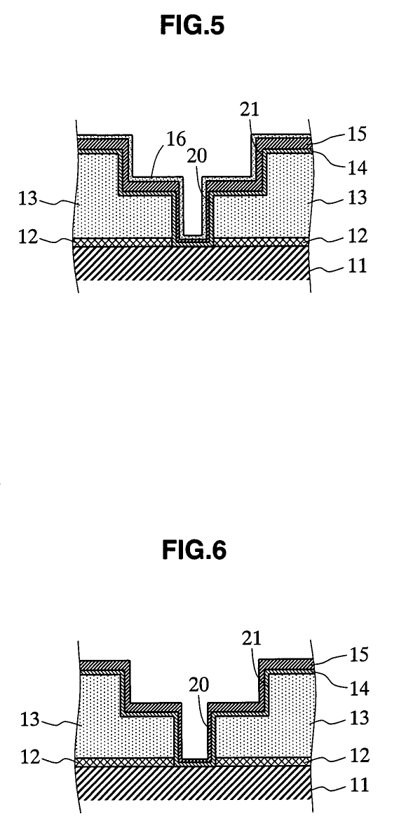

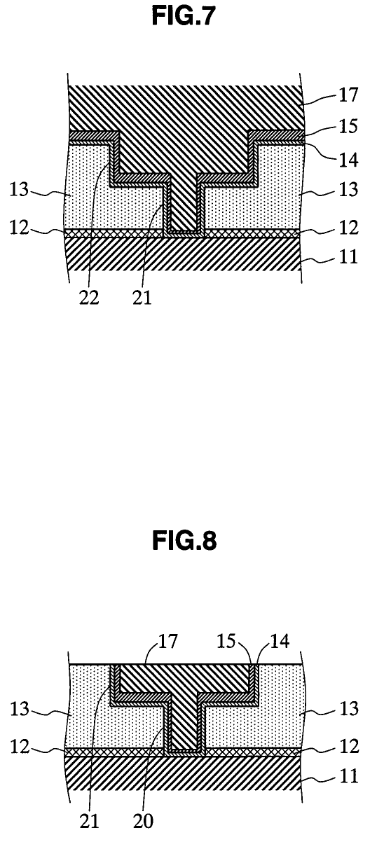

The above electrolytic plating can be done by known electrolytic plating techniques. The semiconductor substrate on which the seed film 15 is formed is immersed in a plating bath of a plating solution containing copper sulfate. The plating bath has a copper electrode serving as the anode electrode. With the seed film 15 serving as the cathode electrode, a predetermined potential difference is applied between the anode and cathode electrodes for copper plating. In this embodiment, as shown in FIG. 6, no area is found where the entire seed film 15 disappears when the semiconductor substrate is immersed in the plating solution. Consequently, as shown in FIG. 7, a copper plating film 17 (a second conductive film) can be formed filling the entire contact hole 20.

The potential difference can be applied between the two electrodes before or after the semiconductor substrate is immersed in the plating solution. The predetermined potential difference can be applied between the two electrodes after a cleaning process is conducted where a reverse bias (in which the cathode electrode has a higher potential) is applied for efficiently removing the oxide from the surface of the seed film 15. Furthermore, the plating solution can contain various extra additives for improved filling although its main component is copper sulfate.

After the copper plating film 17 is formed as described above, the excessive copper plating film 17, the excessive seed film 15, and the excessive conductive barrier film 14 on the interlayer insulating film 13 are removed by CMP. Then, as shown in FIG. 8, an upper wiring consisting of the copper plating film 17, the seed film 15, and the conductive barrier film 14 and a contact plug connecting the upper wiring and the lower wiring 11 are formed, and more upper wiring layers are formed to complete a semiconductor device having a multiplayer wiring structure.

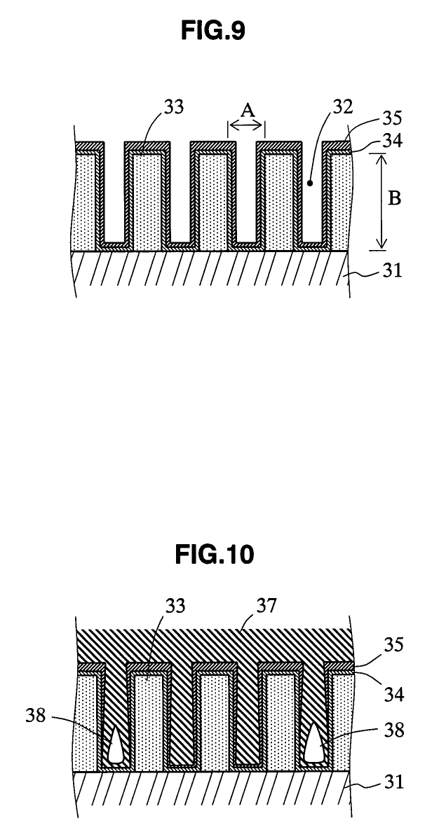

The maximum length of time until the plating is started after the semiconductor substrate is exposed to the atmosphere after the formation of the seed film 15 (hereafter referred to as the maximum time) is determined as follows. FIG. 9 is a cross-sectional view of an evaluation sample used to determine the maximum time.

As shown in FIG. 9, the evaluation sample has an insulating film 33 on a semiconductor substrate 31. Plural trench patterns 32 (line-and-space patterns) are formed through the insulating film 33 by known lithographic and etching techniques. Multiple evaluation samples having different aspect ratios (=the thickness B of the insulating film 33/the opening width A of the trench pattern 32) are used to evaluate void incidence rate over a specific length of time until the plating treatment is started from the time when the semiconductor substrate is exposed to the atmosphere after the formation of the seed film 35 (hereafter referred to as the atmosphere exposure time). In this way, the dependency of void incidence rate on the aspect ratio can be obtained. The void incidence rate is defined as the ratio of the number of trench patterns 32 in which a void 38 has appeared to the number of trench patterns 32 observed when the evaluation samples are observed in a cross-section by an FIB (focused ion beam) after the formation of the plating film 37 (see FIG. 10). For example, when 100 trench patterns 32 are observed and five voids 38 have appeared, the void incidence rate is 5%. If the void incidence rate is 0%, no voids 38 have appeared in any of the trench patterns. In this instance, the insulating film 33 has a fixed thickness B of 700 nm. The evaluation samples were produced by first forming the trench patterns 32, then forming a tantalum nitride conductive barrier film 34 to approximately 25 nm, and further forming a copper seed film 35 to approximately 100 nm. The same plating conditions were applied to all evaluation samples.

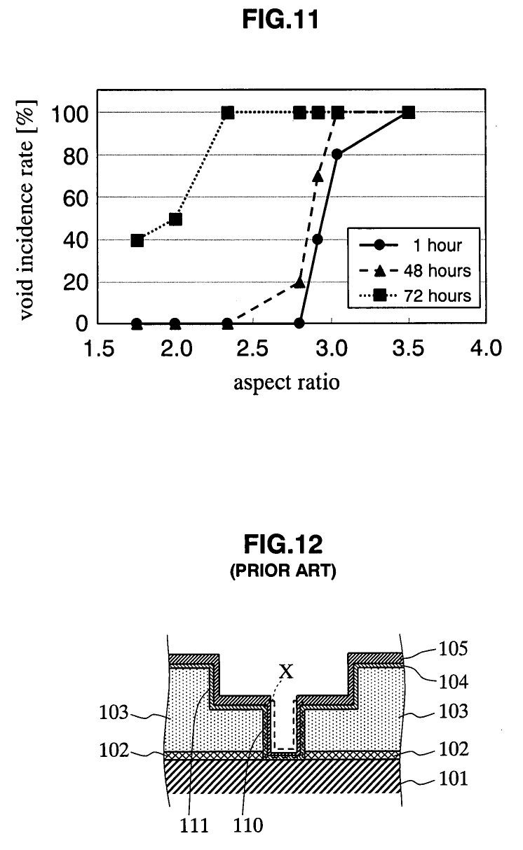

FIG. 11 is a graphic representation showing the dependency of the void incidence rate to the aspect ratio using the atmosphere exposure time as a parameter. The atmosphere exposure time was 1 hour (solid line), 48 hours (broken line), or 72 hours (dotted line). In FIG. 11, the horizontal axis corresponds to the aspect ratio, and the vertical axis corresponds to the void incidence rate.

FIG. 11 shows that when the atmosphere exposure time was 1 hour, no void 38 appeared for the aspect ratio of 2.8 or smaller (the void incidence is 0%). On the other hand, the void 38 appeared in all trench patterns 32 observed for an aspect ratio of 3.5 (the void incidence is 100%). When the atmosphere exposure time was 48 hours, no void 38 appeared and filling was fine for an aspect ratio of 2.4 or smaller. Moreover, when the atmosphere exposure time was 48 hours, the void 38 appeared in all trench patterns 32 observed for an aspect ratio of 3.0 or larger. When the atmosphere exposure time was 72 hours, the void incidence rate was 50% and half the number of trench patterns 32 had a void 38 for an aspect ratio of 2.0. Moreover, the void 38 appeared in all trench patterns 32 observed for an aspect ratio of 2.4 or larger.

As seen from above, the void incidence rate depends on the aspect ratio and the atmosphere exposure time. For example, when the aspect ratio is 2.8, the void incidence rate is 0% for the atmosphere exposure time of 1 hour, 20% for the atmosphere exposure time of 48 hours, and 100% for the atmosphere exposure time of 72 hours. In other words, the void incidence rate is increased as the atmosphere exposure time is increased, because the thickness of the oxidized seed film 35 is increased and the thickness of the unoxidized copper is reduced as the atmosphere exposure time is increased. The seed film 35 dissolves and the conductive barrier film 34 is exposed in a larger area during plating as the atmosphere exposure time is increased.

This phenomenon is particularly apparent on the bottom and lower sidewall of the trench pattern 32 where the seed film 35 has a smaller thickness. As mentioned above, the conductive barrier film 34 has resistance one or two orders larger than copper in the seed film 35. When a plating voltage is applied, the seed film 35 is subject to a desired voltage while the conductive barrier film 34 is not subject to the desired voltage because of voltage drop as a result of the difference in resistance. Therefore, the copper plating film 37 is not deposited at the bottom of the trench pattern 32. The copper plating film 37 is deposited only at the upper part of the trench pattern 32. In this state, the top opening of the trench pattern 32 becomes smaller making it difficult for the plating solution to reach the bottom of the trench pattern 32. Therefore, the copper plating film 37 barely deposits at the bottom of the trench pattern 32. Finally, the trench pattern 32 is closed by the copper plating film 37 at the top and a void 38 is created at the bottom of the trench pattern 32 as shown in FIG. 10.

In order to prevent the appearance of the void 38, for example, the atmosphere exposure time is set for 48 hours or less for the recesses having an aspect ratio of 2.4 or smaller (see FIG. 11). With the maximum atmosphere exposure time being determined based on the aspect ratio, the appearance of the void 38 is prevented. The maximum time varies depending on the shape of the recesses formed in the interlayer insulating film. Therefore, it is preferable that the dependency of void incidence rate on the atmosphere exposure time according to the shape of the recesses be obtained and the maximum time determined based on the dependency. However, the maximum time can be determined based on the dependency of line-and-space patterns on the atmosphere exposure time shown in FIG. 11. In the dual damascene technique shown in FIGS. 1 to 8, the maximum time can be determined based on the graph in FIG. 11 using the thickness of the interlayer insulating film 13 divided by the diameter of the contact hole 20 as a pseudo aspect ratio. When the trench pattern 21 has a significantly smaller aspect ratio than the contact hole 20, the maximum time can be determined based on FIG. 11 using only the aspect ratio of the contact hole 20. For example, in the above case, the contact hole 20 has an inner diameter of approximately 170 nm and a depth of approximately 400 nm; the aspect ratio is approximately 2.35. The atmosphere exposure time of 48 hours or less can prevent the appearance of the void 38.

If semiconductor devices become much smaller and the recesses have higher aspect ratios in the future, the seed film has a further smaller thickness at the bottom of the recesses, reducing the acceptable maximum atmosphere exposure time. With the technique of the present invention, the maximum atmosphere exposure time can easily be obtained for further smaller devices ensuring highly reliable wiring.

According to FIG. 11, for example, the acceptable maximum atmosphere exposure time will be significantly reduced for an aspect ratio of 3 or larger. For example, when the maximum atmosphere exposure time is 1 hour or less, the maximum time is easily consumed in case of failure of the plating unit, leading to defective filling. In order to increase the maximum time, the semiconductor substrate can be maintained in an inert gas such as nitrogen and rare gas until the electrolytic plating is started after the completion of the seed film.

As explained above, the present invention prevents the seed film formed in the recesses of the interlayer film from being oxidized through the entire thickness. Then, when the semiconductor substrate is immersed in a plating solution for filling the recesses with a plating film by electrolytic plating using the seed film as an electrode, no area is observed in the recesses where the seed film dissolves and disappears. Therefore, the plating film can be formed in the recesses without any void, enabling the fabrication of a semiconductor device with highly reliable wiring.

The above embodiment does not restrict the present invention in any technical aspects. Various modifications and applications are available within the scope of the present invention in addition to the above described embodiment. For example, the copper plating is deposited on the copper seed film in the described case. However, the seed film and plating film materials are not restricted to these, and the present invention can be applied to any combination of materials in the method of fabricating a semiconductor device in which the recesses in which a seed film is formed are filled by plating using the seed film as an electrode and the oxidized seed film dissolves in a plating solution.

The present invention has an efficacy that highly reliable wiring with regard to EM resistance and disconnection can be formed and provides a useful method of fabricating a semiconductor device.

While the invention has been shown and described in detail, the foregoing description is in all aspects illustrative and not restrictive. It is therefore understood that numerous modifications and variations can be devised without departing from the scope of the invention.

1. A method for fabricating a semiconductor device having a multilayer wiring structure, comprising the steps of:
forming an interlayer insulating film on a lower wiring;
forming plural recesses in the interlayer insulating film;
forming a first conductive film in the recesses formed in the interlayer insulating film; and
forming a second conductive film by electrolytic plating using the first conductive film as an electrode, wherein
the length of time until the electrolytic plating for forming the second conductive film is started after the completion of the first conductive film is limited to a specific length of time or less determined based on a formation condition of the first conductive film in the recesses.

2. A method for fabricating a semiconductor device according to claim 1, wherein the specific length of time is determined according to the aspect ratio of the recesses.

3. A method for fabricating a semiconductor device according to claim 2, wherein the aspect ratio is 2.4 or smaller and the specific length of time is 48 hours.

4. A method for fabricating a semiconductor device according to claim 1, wherein the specific length of time is determined according to the dependency of void incidence rate on the atmosphere exposure time, the dependency being obtained based on line-and-space patterns having different aspect ratios.

5. A method for fabricating a semiconductor device having a multilayer wiring structure, comprising the steps of:
forming an interlayer insulating film on a lower wiring;
forming plural recesses in the interlayer insulating film;
forming a first conductive film in the recesses formed in the interlayer insulating layer; and
forming a second conductive film by electrolytic plating using the first conductive film as an electrode, wherein
the semiconductor substrate on which the first conductive film is formed is maintained in an inert gas atmosphere until the electrolytic plating for forming the second conductive film is started after the completion of the first conductive film.
